(19) United States
(12) Patent Application Publication
(10) Pub. No.: US 2009/0087673 A1
(43) Pub. Date: Apr. 2, 2009

(54) Method for coating fuel system components

(76) Inventors: Steven C. Taylor, Dunlap, IL (US); Bao Feng, Dunlap, IL (US); Lucy V. Davies, Peoria, IL (US); Jeffrey P. Werner, Peoria, IL (US)

Correspondence Address: CATERPILLAR/FINNEGAN, HENDERSON, L.L.P., 901 New York Avenue, NW, WASHINGTON, DC, 20001-4413, US

(21) Appl. No.: 11/863,777

(22) Filed: Sep. 28, 2007

(51) Int. Cl. B32B 15/04; C23C 14/35

(52) U.S. Cl. 428/472; 204/192.15; 428/457

(57) ABSTRACT

The present disclosure includes a method of producing a fuel system component. The method includes providing a substrate and a coating, wherein the substrate comprises steel and the coating comprises a metal nitride. The method also includes applying the coating to at least part of the substrate using a magnetron sputtering deposition process substantially conducted at a temperature less than about 200° C.

### TECHNICAL FIELD

This disclosure relates to methods for manufacturing fuel system components, and more particularly, to methods for coating fuel system components.

### BACKGROUND

Internal combustion engines, whether compression or spark ignition, require fuel injection systems to precisely and reliably delivery fuel to the engine's combustion chambers. Such precision and reliability are needed to improve fuel efficiency, maximize power output, and reduce undesirable emissions.

Generally, fuel injection systems include a fuel pump and one or more fuel injectors. The fuel pump supplies fuel to the injectors, which subsequently control delivery and timing of the fuel to engine cylinders. One commonly used injector design uses a reciprocating plunger to control fuel delivery to a particular combustion chamber.

To improve operation, hard coatings are applied to components of fuel systems to reduce wear. For example, where opposing surfaces of two components contact one another, a wear resistant coating may be used to reduce component wear. Traditionally it was thought desirable to apply a coating to only one surface of two opposing components. The other opposing surface would often be produced from a bare metal (e.g. steel substrate) or other material softer than the hard coating applied to the opposing surface. In this way, the uncoated bare metal surface could be polished to conform to the coated surface, reducing the overall wear rate.

Various coating methods are known in the art, and one is disclosed in U.S. Pat. No. 4,540,596, which issued to Nimmagadda on Sep. 10, 1985 (hereinafter “the '596 patent”). The '596 patent provides a method for coating bearing surfaces. The method is a modified physical vapor deposition (PVD) process whereby a coating is applied at temperatures that do not exceed 400° Fahrenheit (204° C.). Such a low temperature coating process can be beneficial as the process may not significantly alter the substrate structure or affect heat treatments previously applied to the substrate.

Although the coating method of the '596 patent may provide suitable coatings for some applications, the method of the '596 patent can have several drawbacks. For example, the method uses an arc electrode deposition process to apply the coating. Due to the high deposition rates associated with such processes, it may be difficult to produce thinner coatings using the method of the '596 patent. Further, arc electrode deposition can be an imprecise and inaccurate process, which may make it unsuitable for parts having strict design tolerances. In particular, fuel system components coated by such a process may fail due to fuel leakage or loss of pressure caused by opposing surfaces having unacceptably low engineering tolerances.

### SUMMARY

A first aspect of the present disclosure includes a method of producing a fuel system component. The method includes providing a substrate and a coating, wherein the substrate comprises steel and the coating comprises a metal nitride. The method also includes applying the coating to at least part of the substrate using a magnetron sputtering deposition process substantially conducted at a temperature less than about 200° C.

A second aspect of the present disclosure includes a fuel system assembly having a first component including a first steel substrate and a first coating disposed on at least part of the first steel substrate, wherein the first coating includes a metal nitride. The assembly also includes a second component having a second steel substrate and a second coating disposed on at least part of the second steel substrate, wherein the second component can be configured to engage the first component in at least one of impact engagement and sliding engagement and the second coating includes a metal nitride. At least one of the first coating and the second coating can be at least partially formed in a sputtering system using a sputtering deposition process substantially conducted at a temperature less than about 200° C.

### BRIEF DESCRIPTION OF THE DRAWINGS

FIG. 1 is a cross-sectional view of a mechanically actuated unit injector, according to an exemplary embodiment.

FIG. 2 is a side view of a coated fuel injector plunger, according to an exemplary embodiment.

FIG. 3 illustrates a fuel pump assembly including a nail valve, according to another exemplary disclosed embodiment.

FIG. 4 is a cross-sectional view of two components of a fuel pump including coatings on opposing surfaces of the fuel pump, according to another exemplary embodiment.

FIG. 5 illustrates a temperature profile during a coating procedure, according to an exemplary embodiment.

FIG. 6 is a top view of a sputtering system, according to an exemplary embodiment.

### DETAILED DESCRIPTION

Reference will now be made in detail to present exemplary embodiments, examples of which are illustrated in the accompanying drawings. Whenever possible, the same reference numbers will be used throughout the drawings to refer to the same or like parts.

The present disclosure provides fuel system components including improved coatings and methods for manufacturing these coated components. The coatings are designed to improve component wear properties and reduce fuel system failure. According to one exemplary method of the present disclosure, coatings can be applied to components at temperatures generally lower than tempering temperatures associated with the component substrate materials. Since higher substrate temperatures can alter material properties, or cause unwanted shape distortion via thermal expansion, low-temperature coating procedures can retain desirable component properties more readily than higher temperature coating procedures. Fuel system components coated at lower temperatures using the methods of the present disclosure can be manufactured with higher engineering tolerances than are currently achievable using other coating techniques.

The components of the present disclosure can include any fuel system components or other machine components configured to contact other components. For example suitable fuel system components can include components of fuel injectors or fuel pumps that are in impact or sliding engagement. In one embodiment, such coatings can be applied to opposing surfaces of components in impact engagement. In other embodiments, components can include a fuel injector bore and plunger that include hard coatings on opposing surfaces in sliding engagement, as described in detail below.

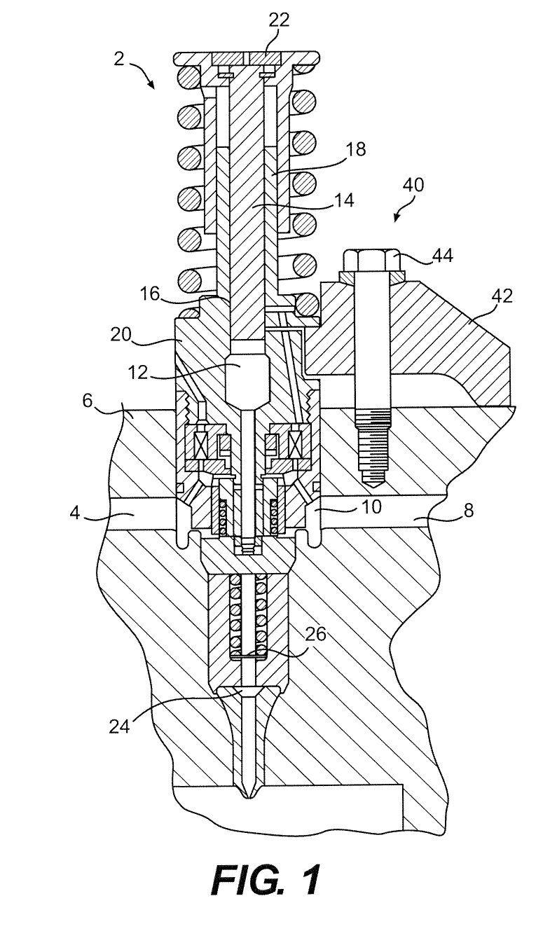

FIG. 1 is a cross-sectional view of a mechanically-actuated unit injector, according to one exemplary embodiment. As shown, an injector 2 includes a fuel injector plunger 14 that reciprocates within a cylindrical bore 16 to pressurize and inject fuel during machine operation. As described in detail below, opposing surfaces of plunger 14 and bore 16 can include surface coatings configured to provide improved resistance to wear and corrosion. Such coatings may also be selected to operate with a variety of different fuels and/or other fluids, including biodiesels, ultra-low sulfur fuels, Toyu fuel, low lubricity fuels, and/or various lubricants.

As shown, fuel injector 2 is mounted on an engine block 6 via a mounting assembly 40, which includes a clamp 42 attached to injector 2, and a bolt 44 that secures clamp 42 to engine block 6. Fuel is provided to fuel injector 2 via a fuel supply conduit 4 formed in engine block 6, and excess fuel drains from injector 2 via a fuel drain conduit 8. Fuel supply conduit 4 and fuel drain conduit 8 are fluidly connected by an annular fuel cavity 10 that surrounds the outer periphery of fuel injector 2.

The fuel supplied by fuel supply conduit 4 periodically flows between injection cycles to a generally cylindrical fuel pressurization chamber 12 formed in the center of fuel injector 2. The fuel in the pressurization chamber 12 is periodically pressurized by fuel injector plunger 14 that reciprocates within cylindrical bore 16 formed in a cylindrical extension 18 of a portion of the fuel injector body 20. As plunger 14 is forced downwards by a rocker arm (not shown) attached to a disk 22, the pressure in pressurizing chamber 12 increases. This pressure increase also increases the pressure in a nozzle cavity 24, which is fluidly connected with chamber 12. When the pressure in nozzle cavity 24 reaches a threshold level, the force exerted by the fluid causes a nozzle check 26 to open, thus causing fuel to be injected into a combustion chamber (not shown).

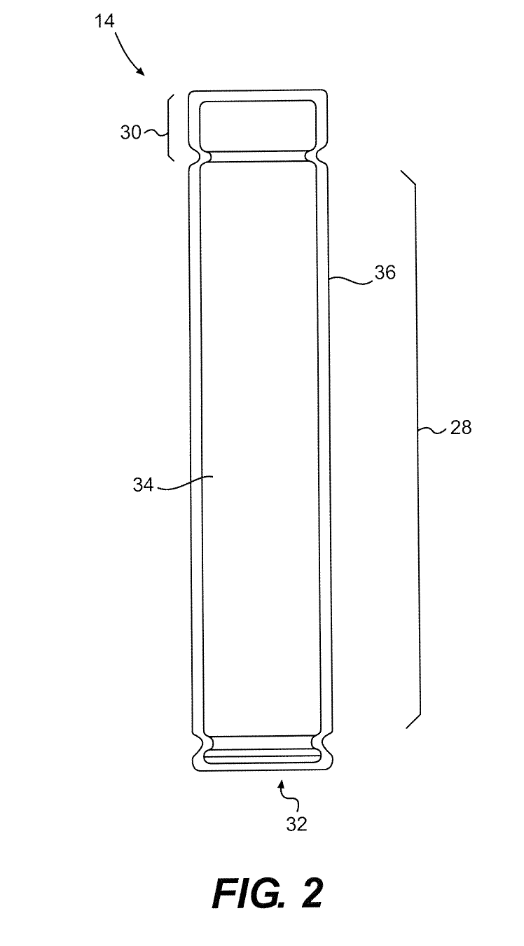

FIG. 2 is a side view of a coated fuel injector plunger 14, according to one exemplary embodiment. As shown, plunger 14 includes a main body section 28, a plunger end section 30, and a loading end section 32. The various sections of fuel injector plunger 14 can be formed or machined from a substrate 34. Plunger 14 can also include a coating 36, which can be applied to at least part of substrate 34 to coat at least part of plunger 14. In some embodiments, another component (not shown) could be configured to engage with plunger 14, such as, for example, bore 16 as shown in FIG. 1. The other component could also be at least partially coated with a coating material such that the two opposed surfaces that contact one another are both coated.

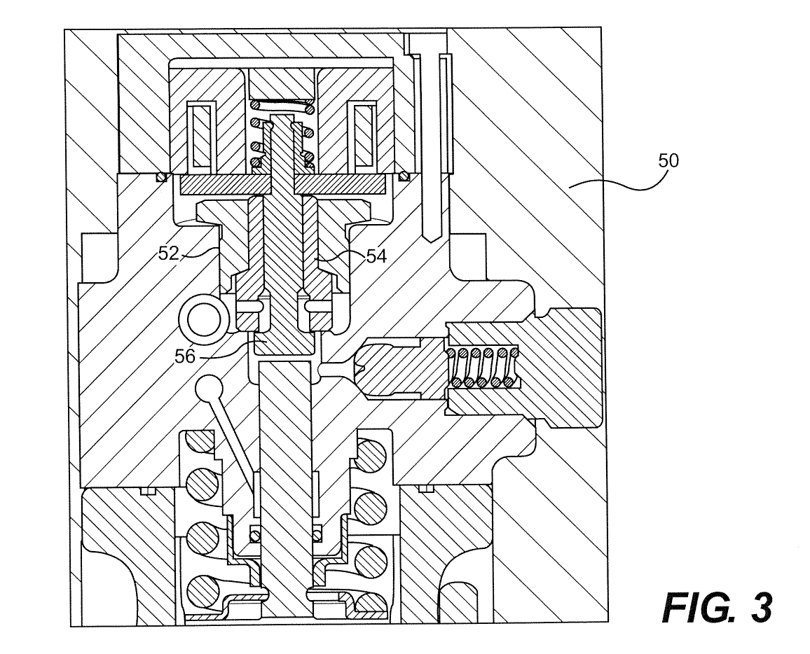

FIG. 3 illustrates a fuel pump assembly 50 including a nail valve assembly 52, according to another exemplary disclosed embodiment. As shown, nail valve assembly 52 includes a moving valve 56 and valve body 54. Further, as shown, valve 56 engages valve body 54 to prevent fuel flow through pump assembly 50. During operation, valve 56 may repeatedly and forcefully engage valve body 54, causing repeated impact between opposing surfaces of valve 56 and valve body 54. To prevent wear of mating surfaces of valve 56 and valve body 54, these surfaces may be produced from or include a coating that will provide resistance to impact and/or sliding wear.

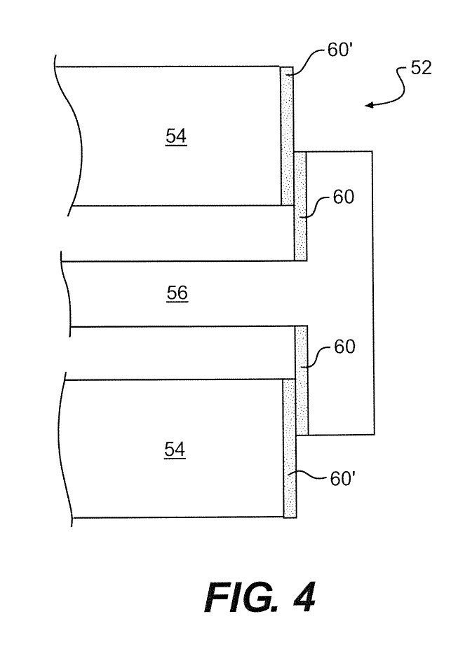

FIG. 4 is a cross-sectional view of nail valve assembly 52 of fuel pump assembly 50, as shown in FIG. 3. As described above, valve assembly 52 includes including coatings 60, 60′ on opposing surfaces of the fuel pump assembly components (valve 56 and valve body 54). As shown, valve 56 and valve body 54 can include coating layers 60, 60′ disposed on substrate materials of valve 56 and valve body 54. In some embodiments, coatings 60, 60′ can be produced from hard, wear-resistant materials. Further, in some embodiments, coatings 60, 60′ can optionally include a bond layer (not shown) between the coatings 60, 60′ and substrates.

As noted, coatings 60, 60′ may include hard, wear resistant materials. Such materials may be selected to prevent wear of machine components that are configured to repeatedly engage one another to produce impact between the two surfaces. Suitable coating materials can also be selected for one or both opposing surface of components configured for sliding engagement, such as, for example, materials suitable for coating 36.

The composition of coatings 36, 60, 60′ may be selected from various suitable materials. In some embodiments, coatings 36, 60, 60′ could include a metal nitride. In particular, coatings 36, 60, 60′ can include at least one metal nitride selected from chromium nitride, zirconium nitride, molybdenum nitride, titanium-carbon-nitride, or zirconium-carbon-nitride. Further, coating 60 on the moving valve 56 may include the same or a similar material used to produce coating 60′ on the opposing surface of valve body 54. For example, in one embodiment, coating 60 and coating 60′ can both include metal nitride. Specifically, coating 60 and coating 60′ can both include chromium nitride.

Various substrates configured for coating can be produced from a number of suitable materials. For example, substrate 34, valve body 54, or valve 56 could include any suitable steel, such as a low alloy steel, a tool steel, 52100 steel, 1120 steel, H10 steel or any other material having similar properties. Suitable materials can be selected based on desired physical properties (e.g., resistance to deformation), and/or ability to bond with overlying coatings and to withstand elevated temperatures, as may be present during coating deposition or device use.

In some embodiments, various substrates, including plunger 14, bore 16, valve body 54, or valve 56, can include a low alloy steel. The term low alloy, as used herein, will be understood to refer to steel grades in which the hardenability elements, such as manganese, chromium, molybdenum and nickel, collectively constitute less than about 3.5% by weight of the total steel composition. Further, low alloy steel may be selected for fuel system components due to relatively low cost and high reliability of such steel.

In addition, materials used to form a component substrate can be selected based on one or more properties of the coating materials. For example, a substrate material may be selected based on the compatibility of a substrate material with a coating material. Compatibility may be based on energy impact response, hardness, wear resistance, thermal expansion, adhesion, or other physical parameters associated with the coating or substrate. In some embodiments, these coatings can be applied to a suitable substrate using a coating method configured to at least partially preserve compatibility properties of the coating and substrate. For example, a coating and substrate may be selected to substantially maintain one or more physical properties, such as, hardness or a physical dimension. Such components may have generally similar physical properties before and after a coating method.

As noted, depending on the intended application and environment of the fuel injector or fuel pump component 52, a bond layer (not shown) may be applied to the substrate before application of coatings 36, 60, 60′. For example, suitable bond layers may include a layer of chromium or other suitable metal layer to the substrate of plunger 14, bore 16, valve 56 or valve body 54 to provide improved adhesion of coatings 36, 60, 60′. If used, the optional bond layer material can be applied using a deposition process to yield a layer having a thickness of generally between about 0.05 microns and about 0.5 microns. Further, the thickness of coatings 36, 60, 60′ on plunger 14, bore 16, valve 56 or valve body 54 should be fairly uniform as measured on a sample of the fuel system components by the Ball Crater Test at a plurality of locations on the components. Alternatively, uniform coating thickness can be demonstrated using scanning electron microscopy measurements on a sample of selected cross sections of the fuel pump components, or through the use of X-ray fluorescence.

Coating 36, 60, 60′ can have a range of suitable thicknesses. For example, these coatings may generally have a thickness no greater than about 5.0 microns, and may generally be between about 0.5 microns and about 1.7 microns, or between about 0.5 microns and about 1.0 microns.

Control of some or all of the physical properties of coatings 36, 60, 60′ and coated component substrates other than thickness may also be relevant to producing a highly reliable and cost effective component. For example, coating adhesion, coating hardness, substrate hardness, surface texture, thermal expansion and frictional coefficients are some of the physical properties that may be monitored and controlled to produce components with desired physical properties. Components requiring specific properties may require certain types of coating methods as not all methods may produce high quality coating and preserve desired substrate properties.

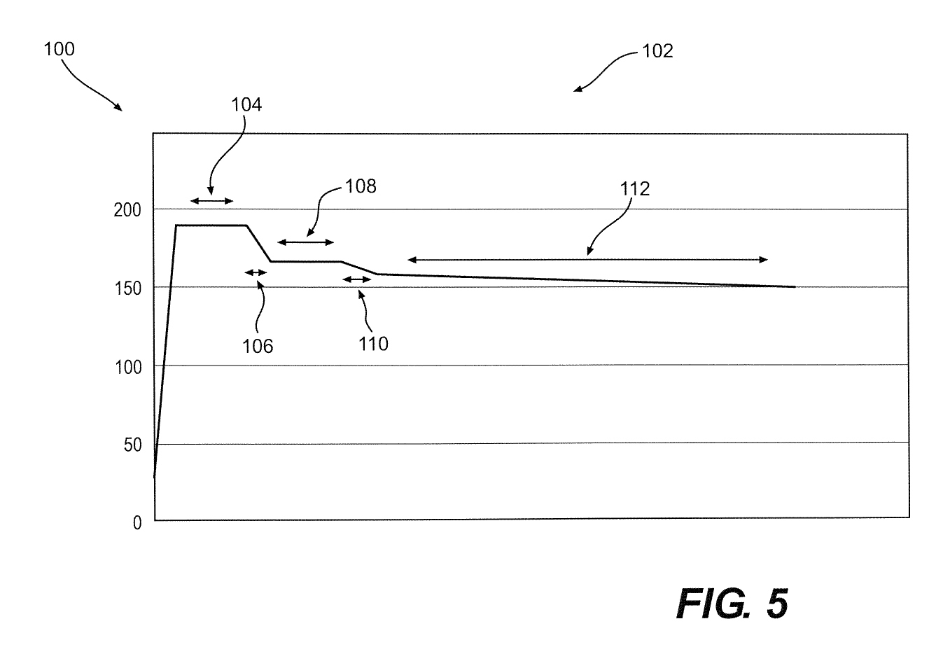

FIG. 5 illustrates a coating production procedure 102, according to one exemplary embodiment. In some embodiments, coating production procedure 102 can be applied to one or more fuel system components, such as, for example, a control valve. In particular, coating procedure 102 can be applied to one or more surfaces of fuel injector plunger 14, fuel injector bore 16, valve body 54, or nail valve 56.

As shown in FIG. 5, coating production procedure 102 includes temperatures generally less than 200° C. If such temperatures can be generally maintained below a substrate material's tempering temperature, mechanical properties imparted by a heat treatment or other thermal processing prior to coating production procedure 102 can be preserved. While high coating temperatures traditionally associated with some coating methods can reduce desirable physical properties of the substrate material, or deform the substrate, low temperature coating can assist preservation of desirable physical properties achieved prior to substrate coating, or reduce thermal deformation of the substrate. In some embodiments, coating production procedure 102 can include temperatures greater than 200° C. Such temperatures could be possible if maintained for relatively short periods of time or if such higher temperatures do not significantly affect material properties or a previously applied thermal treatment.

Prior to coating procedure 102, a compatible substrate and coating materials can be selected, as previously described. The substrate material may then be manufactured into a form configured to engage another component, wherein the other component may be coated or uncoated. Engagement can include sliding or impact of opposing component surfaces. Further, various other manufacturing processes can be applied to the substrate material or formed substrate prior to coating procedure 102. For example, substrate cleaning can be accomplished through a number of conventional methods such as degreasing, grit blasting, etching, chemically assisted vibratory techniques, ultrasonic cleaning with an alkaline solution, and the like. Cleaning could also include an inspection step to confirm suitable cleaning.

Coating procedure 102 can include one or more phases or sub-processes. As shown in FIG. 5, coating procedure 102 can include a pre-heating process 104, a target cleaning process 106, a heating process 108, a plasma etching process 110, and a coating process 112. In other embodiments, coating procedure 102 can include fewer processes, repeated processes, or other processes administered prior to, following, or during coating process 112.

Pre-heating process 104 can include initially heating a component, such as substrate 34, to a select temperature range to elevate a component's temperature in preparation for coating process 112 or to aid removal of surface debris. Coating procedure 102 can also include one or more heating processes 108, or cooling processes (not shown), to control component temperature or surrounding temperature, as described in detail below. Such controlled heat treatment can help reduce unwanted changes in substrate dimensions during coating procedure 102.

Target cleaning process 106 can include any process designed to at least partially clean a sputtering target. Cleaning process 106 can include any number of steps, and some steps can be repeated multiple times in order to achieve suitable cleaning.

Coating procedure 102 can also include one or more surface treatment processes at various stages throughout component coating. Surface treatments can be performed to enhance coating adhesion or to affect coating structure. For example, a highly smooth substrate surface can be produced by a grinding process or by ion-etching surface using argon. In some embodiments, plasma etching process 110 can be applied whereby a high-speed stream of plasma is shot (in pulses) at a substrate surface. Other similar processes can also be applied prior to coating process 112.

Coating process 112 can include any suitable sputtering deposition process, such as, for example, magnetron sputtering. In some embodiments, coating process 112 can be substantially conducted at a temperature less than about 200° C. In other embodiments, as shown in FIG. 5, coating process 112 can be substantially conducted at a temperature less than about 160° C. Further, hybrid procedures can be used whereby at least part of the coating is applied using a sputtering deposition process conducted at a temperature less than about 200° C.

Suitable sputtering processes generally include bombarding a target material with energetic ions, usually an inert gas, such as, for example, argon. Atoms in the target material are then ejected into a gas phase due to the bombardment. These atoms are then accelerated towards a substrate and small amounts of the target material are deposited on a substrate surface.

Sputtering sources can include magnetrons that utilize strong electric and magnetic fields to trap electrons close to the surface of the magnetron target. Magnetrons generally require relatively high levels of substrate ion bombardment, which can be achieved by increasing the power to the target or decreasing the distance from the target. In some embodiments, coating process 112 can also include unbalanced magnetron sputtering.

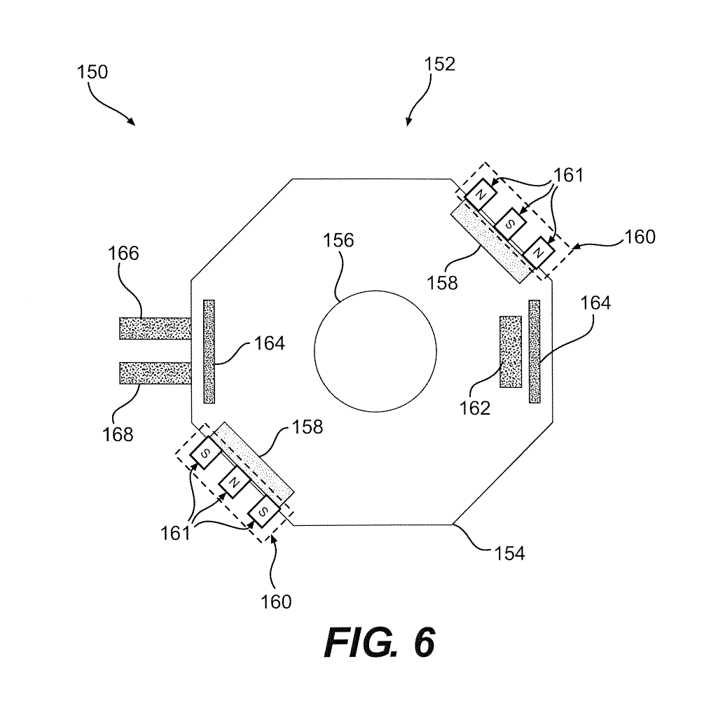

FIG. 6 is a top view of a sputtering system 150, according to one exemplary embodiment. In some embodiments, sputtering system 150 can include an unbalanced magnetron sputtering (UBMS) system 152. UBMS system 152 can include a coating chamber 154, a substrate table 156, one or more sputtering targets 158, a plurality of unbalanced magnetrons 160, a magnetron magnet 161, a plasma source 162, one or more heating elements 164, a gas supply 166, and an inert gas supply 168.

Coating chamber 154 can include any suitable vacuum chamber configured to operate with an UBMS coating process. Coating chamber 154 can be further configured to house substrate table 156 configured to retain one or more components to be coated (not shown). In some embodiments, substrate table 156 can rotate or move relative to one or more sputtering targets 158.

Sputtering targets 158 can include any suitable material operable with sputtering system 150, such as, for example, a material containing chromium. Various materials can be selected based on the specific requirements of the sputter process, substrate to be coated, or coating material. Sputtering targets 158 are usually positioned adjacent to unbalanced magnetrons 160. The unbalanced magnetic fields produced by magnetrons 160 cause expansion of the plasma away from the surface of target 158 towards substrate table 156 and the substrate (not shown) to be coated.

In some embodiments, magnetron magnets 161 can be arranged with adjacent alternating poles, resulting in linked, or closed, field lines between various magnetrons 160. These field lines can prevent electrons from escaping to the walls of chamber 154, resulting in higher ion current densities and harder, well-adhered coatings. Suitable UBMS systems are manufactured by TEER Coatings Ltd. (Worcester, UK).

UBMS system 152 can also include plasma source 162, configured to provide a source of plasma. Heating element 164 can be configured to heat chamber 154 to any suitable temperature, such as, for example, temperature profile 100 as shown in FIG. 5. UBMS system 152 can further include one or more gas supplies. As shown in FIG. 6, gas supply 166 and inert gas supply 68 are fluidly connected to chamber 154. For example, gas supply 166 could include a supply of argon gas and inert gas supply 168 could include a supply of nitrogen gas. Gas supplies 166, 168 may each include valves (not shown) or other devices (not shown) configured to independently control gas flow into chamber 154.

To form a coating of suitable quality, parameters associated with a sputtering deposition process may be selected based on the type of substrate material or operational requirements of the fuel system component. Some substrates may be affected by elevated temperatures, and coating process 112 may be selected to minimize adverse effects of the process on selected substrates, e.g., by limiting the process temperature or coating time. Sputtering processes may be selected to produce chromium nitride (CrN) coatings, and suitable processes may be selected to maintain temperatures below 160° C. to reduce dimensional changes in underlying substrates or loss of desired mechanical properties.

Generally, several parameters associated with the operation of UBMS system 152 can affect coating process 112. Specifically, particular “recipes” of parameter settings can be used to produce coated components with particular properties. In some embodiments, coating quality can be influenced by gas pressure, magnetron strength and substrate bias. Different recipes, or parameter settings, associated with UBMS system 152 can be balanced to optimize component properties, such as, for example, hardness, Young's modulus, brittleness, wear resistance, or friction coefficients. Controlling gas pressure, magnetron strength or substrate bias can affect the plasma characteristics of the coating process, and thus influence coating deposition rate, chemical deposition, and material microstructure to vary mechanical and tribological properties of the coated product.

Suitable recipes for use with UBMS system 152 can also be affected by the substrate material and the general temperature maintained during coating process 112. For example, a CrN coating can be formed on a steel substrate when coating process 112 is generally conducted at a temperature less than about 160° C., and when system 152 has a gas pressure of about 3E-3 mbar, a nitrogen partial pressure about 3E-5 mbar, a cathode power density of about 1-3 W/cm², a substrate bias of about 100-150 volts, and coating process 112 is maintained for about 4-8 hours. Such a recipe can result in a hard CrN coating having a thickness of about 1-2 μm and a nano-hardness of about 20 GPa while maintaining thermal expansion of the substrate to engineering tolerances less about 1 μm.

Control of at least some of the physical or chemical properties of the coating or substrate, other than thickness, can also be relevant to producing a highly-reliable and cost-effective component. For example, coating adhesion, coating hardness, substrate hardness, surface texture, and friction coefficients are some of the physical properties that may be monitored and controlled to produce desirable fuel injector components. Further, different applications may demand different physical or chemical properties.

As indicated above, any formed coating should be generally free of surface defects. Further, the coating can include specified surface texture ratings or surface texture measurements dependent on the intended use of the component. For example, surface defects can generally be observed on a sample of coated substrates through the observation of multiple points on the surface of the samples at about one hundred times magnification. The surface observations can be compared to various classification standards to ensure the coating is substantially free from surface defects. In addition, the coating should generally adhere to the selected substrate material. Coating adhesion can be assessed for a given population of fuel system components, for example, by using standard hardness tests (e.g., Rockwell C hardness measurements) in which impact locations on component surfaces are observed and compared to various adhesion classification standards.

Finally, it should be noted that although the disclosed coatings are described for use with plunger 14, bore 16, valve body 54, and nail valve 56, the disclosed coatings may be used with any machine components that are subject to repeated impact and/or sliding engagement. Further, such coatings may be used with any machine components subject to these forms of wear, in the presence of various hydrocarbon fuels or fuel additives. For example, such components can include any valves or other components used in fuel pumps, fuel injectors, or other engine components that may be subject to wear.

### INDUSTRIAL APPLICABILITY

The present disclosure provides a low temperature coating method for fuel system components. Such low temperature processing can aid preservation of material properties produced by prior heat treatments applied to the components, thereby improving wear resistance and reducing failure rates. The component can include a substrate and coating deposited on the substrate. The coating can include a number of suitable hard materials, such as a metal nitride material. In some embodiments, a coating of chromium nitride can be applied to a steel substrate.

The low temperature coating process can include any suitable sputtering deposition technique, such as, for example, magnetron sputtering or unbalanced magnetron sputtering. Prior to coating, a substrate material may be cleaned, heated, and/or surface treated as required. During a coating process, the substrate may be coated while the temperature remains below about 200° C. In some embodiments, the coating temperature may be about 160° C. Also, one or both opposing surfaces of two components may be coated using such a coating process. As previously noted, components in sliding or impact engagement wherein both opposed surfaces are coated can show significantly reduced component wear than when only one surface is coated.

Certain parameters of the deposition system may be modified to permit formation of a hard, thin coating on at least part of a component substrate, as previously described. Particular recipes for the operation of sputtering systems may produce components with significantly improved physical properties. For example, a fuel system component may be partially coated with a coating having a thickness between 0.05 μm and 2 μm. Using the coatings of the present disclosure on opposing surfaces can provide low component wear rates in the presence of convention engine fuels, but also in the presence of alternative fuels, such as low-lubricity fuels, Caterpillar fuels, biodiesels, Toyu fuel, JPS, and K1 fuel.

It will be apparent to those skilled in the art that various modifications and variations can be made in the disclosed systems and methods without departing from the scope of the disclosure. Other embodiments of the disclosed systems and methods will be apparent to those skilled in the art from consideration of the specification and practice of the embodiments disclosed herein. It is intended that the specification and examples be considered as exemplary only, with a true scope of the disclosure being indicated by the following claims and their equivalents.

What is claimed is:

1. A method of producing a fuel system component, comprising:
providing a substrate and a coating, wherein the substrate comprises steel and the coating comprises a metal nitride; and
applying the coating to at least part of the substrate using a magnetron sputtering deposition process substantially conducted at a temperature less than about 200° C.

2. The method of claim 1, wherein the metal nitride is selected from the group consisting of chromium nitride, zirconium nitride, molybdenum nitride, titanium-carbon-nitride, and zirconium-carbon-nitride.

3. The method of claim 1, wherein the substrate is selected from the group consisting of low-alloy steel, tool steel, 52100 steel, 1120 steel and H10 steel.

4. The method of claim 1, wherein the substrate is configured to engage another component in at least one of impact engagement and sliding engagement.

5. The method of claim 1, wherein the deposition process includes unbalanced magnetron sputtering.

6. The method of claim 1, wherein the deposition process is substantially conducted at a temperature less than about 160° C.

7. The method of claim 6, wherein the deposition process includes providing a gas pressure of about 3E-3 mbar and a nitrogen partial pressure of about 3E-5 mbar.

8. The method of claim 6, wherein the deposition process includes providing a cathode power density in a range between about 1 W/cm² and about 3 W/cm² .

9. The method of claim 6, wherein the deposition process includes providing a substrate bias in a range between about 100 volts and about 150 volts.

10. The method of claim 6, wherein the deposition process is conducted for a time in a range between about 4 hours and about 8 hours.

11. The method of claim 1, further including a coating process substantially conducted at a temperature less than about 200° C., wherein the coating process is selected from the group consisting of a pre-heating process, a target cleaning process, a heating process, and a plasma etching process.

12. A fuel system assembly, comprising:
a first component comprising a first steel substrate and a first coating disposed on at least part of the first steel substrate, wherein the first coating comprises a first metal nitride;
a second component comprising a second steel substrate and a second coating disposed on at least part of the second steel substrate, wherein the second component is configured to engage the first component in at least one of impact engagement and sliding engagement and the second coating comprises a second metal nitride; and
at least one of the first coating and the second coating is at least partially formed in a sputtering system using a sputtering deposition process substantially conducted at a temperature less than about 200° C.

13. The fuel system assembly of claim 12, wherein at least one of the first and the second metal nitride includes a material selected from the group consisting of chromium nitride, zirconium nitride, molybdenum nitride, titanium-carbon-nitride, and zirconium-carbon-nitride.

14. The fuel system assembly of claim 12, wherein at least one of the first steel substrate and the second steel substrate includes a material selected from the group consisting of low-alloy steel, tool steel, 52100 steel, 1120 steel and H10 steel.

15. The fuel system assembly of claim 12, wherein the deposition process is substantially conducted at a temperature less than about 160° C.

16. The fuel system assembly of claim 12, wherein the deposition process includes at least one of magnetron sputtering and unbalanced magnetron sputtering.

17. The fuel system assembly of claim 12, wherein the sputtering system provides a gas pressure of about 3E-3 mbar and a nitrogen partial pressure of about 3E-5 mbar.

18. The fuel system assembly of claim 12, wherein the sputtering system provides a cathode power density in a range between about 1 W/cm² and about 3 W/cm².

19. The fuel system assembly of claim 12, wherein the sputtering system provides a substrate bias in a range between about 100 volts and about 150 volts.

20. The fuel system assembly of claim 12, wherein the deposition process is conducted for a time in a range between about 4 hours and about 8 hours.

21. The fuel system assembly of claim 12, wherein at least one of the first steel substrate and the second steel substrate is further treated with a coating process substantially conducted at a temperature less than about 200° C., wherein the coating process is selected from the group consisting of a pre-heating process, a heating process, and a plasma etching process.
